(19) United States
(12) Patent Application Publication
(10) Pub. No.: US 2024/0397802 A1
(43) Pub. Date: Nov. 28, 2024

(54) DISPLAY DEVICE

(71) Applicant: Samsung Display Co., LTD., Yongin-si (KR)

(72) Inventors: Jin Su LEE, Yongin-si (KR); Chang Wook KIM, Yongin-si (KR); Hong Jo PARK, Yongin-si (KR); Eung Gyu LEE, Yongin-si (KR); Eun Je JANG, Yongin-si (KR); Seong Min CHO, Yongin-si (KR)

(21) Appl. No.: 18/594,298

(22) Filed: Mar. 4, 2024

(30) Foreign Application Priority Data
May 22, 2023 (KR) 10-2023-0065872

(51) Int. Cl. H10K 59/80; G06F 3/041; G06F 3/044; H10K 59/35

(52) U.S. Cl. CPC H10K 59/8791; G06F 3/0412; G06F 3/0443; G06F 2203/04111; H10K 59/35

(57) ABSTRACT

A display device includes: a base layer; and sub-pixels disposed on the base layer, the sub-pixels including first sub-pixels and second sub-pixels. The first sub-pixels may include a first sub-pixel and a first adjacent sub-pixel, the second sub-pixels may include a second sub-pixel, and the second sub-pixel may be disposed between the first sub-pixel and the first adjacent sub-pixel. The first sub-pixel may include a first color filter and a first refractive layer disposed on the first color filter. The first adjacent sub-pixel may include a first adjacent color filter disposed in the same layer as the first color filter. A refractive index difference between the first color filter and the first refractive layer may be different from a refractive index difference between the first adjacent color filter and a layer disposed directly on the first adjacent color filter.

The application claims priority to Korean patent application No. 10-2023-0065872, filed on May 22, 2023, and all the benefits accruing therefrom under 35 U.S.C. § 119, the content of which in its entirety is herein incorporated by reference.

### BACKGROUND

### 1. Field

The disclosure generally relates to a display device.

### 2. Description of the Related Art

As an application field of display devices is further expanded, demands for high-quality display devices are being increased.

A light-emitting structure inside a display device may emit light to the outside. At least some of components of the display device may reflect light applied from the outside. When the light applied from the outside is reflected, a user may view two or more images according to a phase of the reflected light.

Such a phenomenon may cause a risk that the display quality of the display device will be damaged, and accordingly, a structure for improving the external visibility of the display device has been researched.

### SUMMARY

Embodiments provide a display device capable of enhancing the display quality of the display device by improving the external visibility of the display device.

In an embodiment of the disclosure, there is provided a display device including: a base layer; and sub-pixels disposed on the base layer, the sub-pixels including first sub-pixels and second sub-pixels, where the first sub-pixels include a first sub-pixel and a first adjacent sub-pixel, the second sub-pixels include a second sub-pixel, and the second sub-pixel is disposed between the first sub-pixel and the first adjacent sub-pixel, where the first sub-pixel includes a first color filter and a first refractive layer disposed on the first color filter, where the first adjacent sub-pixel includes a first adjacent color filter disposed in the same layer as the first color filter, and where a refractive index difference between the first color filter and the first refractive layer is different from a refractive index difference between the first adjacent color filter and a layer disposed directly on the first adjacent color filter.

In an embodiment, the second sub-pixels may include the second sub-pixel disposed in each of a first area, a second area, and a third area, which are sequentially disposed adjacent to each other. The second sub-pixel disposed in the second area may include a second color filter and a second refractive layer disposed on the second color filter. The second sub-pixel disposed in the first area and the second sub-pixel disposed in the third area may not include the second refractive layer.

In an embodiment, the first refractive layer may not overlap with the first adjacent color filter in a plan view. The first refractive layer may contact a top surface of the first color filter.

In an embodiment, the display device may further include an overcoat layer entirely covering each of the first color filter and the first adjacent color filter. The overcoat layer may not contact the top surface of the first color filter but in contact with a top surface of the first adjacent color filter. The first refractive layer may have a first refractive index greater than a refractive index of the overcoat layer and a refractive index of the first color filter. The first refractive index may be 1.5 or more.

In an embodiment, the first refractive layer may include an inorganic material or an organic material, which has a refractive index of 1.5 or more. The inorganic material may include at least one of copper (Cu), iodine (I), thallium (Tl), silver (Ag), cadmium (Cd), mercury (Hg), tin (Sn), lead (Pb), zinc (Zn), and iron (Fe), or a metal oxide such as titanium oxide (TiOₓ), tantalum oxide (TaOₓ), hafnium oxide (HfOₓ), and zirconium oxide (ZrOₓ). The organic material may include at least one of PEDOT, TPD, m-MTDATA, o-MTDAB, m-MTDAB, p-MTDAB, BPPM, TPBI, and TAZ.

In an embodiment, external light applied to the display device may have a first phase when the external light is transmitted through the first refractive layer. The external light applied to the display device may have a second phase when the external light is not transmitted through the first refractive layer. The first phase and the second phase may be different from each other.

In an embodiment, the sub-pixels may further include third sub-pixels. The second sub-pixels may further include a second adjacent sub-pixel adjacent to the second sub-pixel with the first sub-pixel interposed therebetween. The second sub-pixel may include a second color filter disposed in the same layer as the first color filter and a second refractive layer disposed on the second color filter. The second adjacent sub-pixel may include a second adjacent color filter disposed in a same layer as the second color filter. The third sub-pixel may include a third color filter disposed in the same layer as the first color filter and a third refractive layer disposed on the third color filter.

In an embodiment, the first refractive layer may have a first thickness, the second refractive layer may have a second thickness, and the third refractive layer may have a third thickness. The first thickness, the second thickness, and the third thickness may be different from one another.

In an embodiment, the first refractive layer, the second refractive layer, and the third refractive layer may have a first refractive index, a second refractive index, and third refractive index, which are different refractive indices of 1.5 or more, as refractive indices greater than refractive indices of the first color filter, the second color filter, and the third color filter.

In an embodiment, the first refractive layer, the second refractive layer, and the third refractive layer may have a first refractive index, a second refractive index, and third refractive index, which are a same refractive index of about 1.5 or more, as refractive indices greater than refractive indices of the first color filter, the second color filter, and the third color filter.

In an embodiment of the disclosure, there is provided a display device including: a base layer; and sub-pixels disposed on the base layer, the sub-pixels including first sub-pixels and second sub-pixels, where the first sub-pixels include a first sub-pixel and a first adjacent sub-pixel, the second sub-pixels include a second sub-pixel, and the second sub-pixel is disposed between the first sub-pixel and the first adjacent sub-pixel, where the first sub-pixel includes a first color filter and a first refractive layer disposed on the first color filter, where the first adjacent sub-pixel includes a first adjacent color filter disposed in the same layer as the first color filter and a first adjacent refractive layer disposed on the first adjacent color filter, and where a phase of light transmitted through the first refractive layer and a phase of light transmitted through the first adjacent refractive layer are different from each other.

In an embodiment, the display device may further include light-blocking members disposed between the first adjacent color filter and the first color filter. The first refractive layer may contact the first color filter, and may not contact the light-blocking members. The first adjacent refractive layer may contact the first adjacent color filter, and may not contact the light-blocking members.

In an embodiment, the display device may further include an overcoat layer entirely covering the first adjacent color filter and the first color filter. The first refractive layer may have a first refractive index greater than a refractive index of the first color filter and the overcoat layer. The first adjacent refractive layer may have a first adjacent layer refractive index greater than a refractive layer of the first adjacent color filter and the overcoat layer. Each of the first refractive index and the first adjacent layer refractive index may be 1.5 or more.

In an embodiment, the first refractive index and the first adjacent layer refractive index may be different from each other.

In an embodiment, the first refractive layer may have a first thickness. The first adjacent refractive layer may have a first adjacent layer thickness different from the first thickness.

In an embodiment, the sub-pixels may further include third sub-pixels. The second sub-pixel may include a second color filter disposed in the same layer as the first color filter and a second refractive layer which is disposed on the second color filter and contacts the second color filter. At least one of the third sub-pixel may include a third color filter disposed in the same layer as the first color filter and a third refractive layer which is disposed on the third color filter and contacts the third color filter.

In an embodiment, the first refractive layer may have a first thickness, the second refractive layer may have a second thickness, and the third refractive layer may have a third thickness. The first thickness, the second thickness, and the third thickness may be different from one another.

In an embodiment of the disclosure, there is provided a display device including: a display unit including a light-emitting element; and an outer part on the display unit, where the outer part includes: color filters disposed above the light-emitting element; light-blocking members disposed between the color filters; and a refractive layer disposed over the color filters and the light-blocking members and covering an entirety of a top surface of each of the color filters and the light-blocking members, and where the refractive layer has a refractive index of 1.5 or more as a refractive index greater than a refractive index of the color filters.

In an embodiment, the color filters may include a first color filter through which light of a first color is transmitted, a second color filter through which light of a second color is transmitted, and a third color filter through which light of a third color is transmitted. The refractive layer may have a first thickness defined in an area overlapping with the first color filter, a second thickness defined in an area overlapping with the second color filter, and a third thickness defined in an area overlapping with the third color filter. The first thickness, the second thickness, and the third thickness may be different from one another.

In an embodiment, the refractive layer may include an area light-exposed according to different times. The area light-exposed according to the different times may include an area overlapping with the first color filter, an area overlapping with the second color filter, and an area overlapping with the third color filter. As the area light-exposed according to the different times is exposed according to different times, the first thickness, the second thickness, and the third thickness may be different from one another.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a schematic view illustrating an embodiment of a display device in accordance with the disclosure.

FIG. 2 is a schematic cross-sectional view illustrating an embodiment of a stacked structure of the display device in accordance with the disclosure.

FIG. 3 is a schematic cross-sectional view illustrating an embodiment of a display unit in accordance with the disclosure.

FIG. 4 is a schematic cross-sectional view illustrating an embodiment of a sensing unit in accordance with the disclosure.

FIG. 5 is a schematic view illustrating an embodiment of a pixel in accordance with the disclosure.

FIG. 6 is a schematic view illustrating a diffraction pattern of light applied to the display device from the outside of the display device.

FIGS. 7 and 8 are schematic cross-sectional views of a display device in accordance with a first embodiment of the disclosure.

FIGS. 9 and 10 are schematic views illustrating an embodiment of a phase change of reflected light of the display device in accordance with the disclosure.

FIG. 11 is a schematic view illustrating an embodiment of a diffraction pattern of light transmitted through a refractive layer of the display device in accordance with the disclosure.

FIG. 12 is a schematic cross-sectional view of a display device in accordance with a second embodiment of the disclosure.

FIG. 13 is a schematic cross-sectional view of a display device in accordance with a third embodiment of the disclosure.

### DETAILED DESCRIPTION

The disclosure may apply various changes and different shape, therefore only illustrate in details with particular examples. However, the examples do not limit to certain shapes but apply to all the change and equivalent material and replacement. The drawings included are illustrated a fashion where the drawing figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

The term such as “part” or “unit” as used herein is intended to mean a software component or a hardware component that performs a predetermined function. The hardware component may include a field-programmable gate array (“FPGA”) or an application-specific integrated circuit (“ASIC”), for example. The software component may refer to an executable code and/or data used by the executable code in an addressable storage medium. Thus, the software components may be object-oriented software components, class components, and task components, and may include processes, functions, attributes, procedures, subroutines, segments of program code, drivers, firmware, micro codes, circuits, data, a database, data structures, tables, arrays, or variables, for example.

The disclosure generally relates to a display device. Hereinafter, a display device in an embodiment of the disclosure will be described with reference to the accompanying drawings.

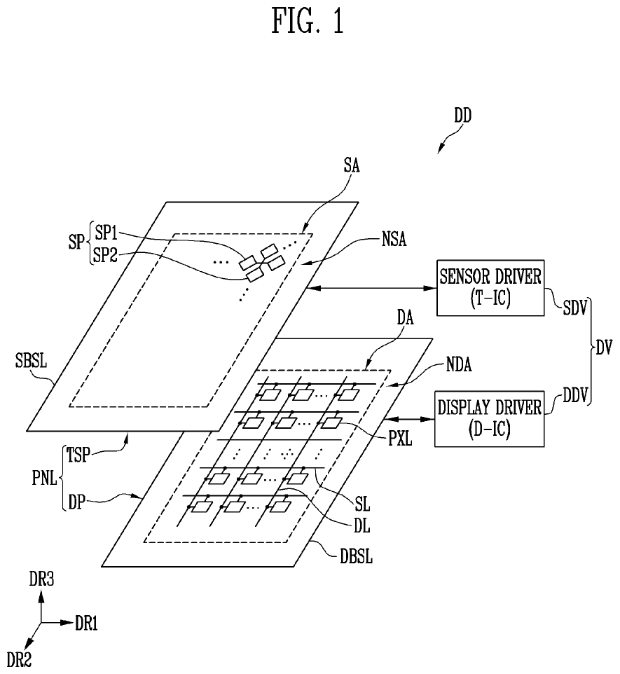

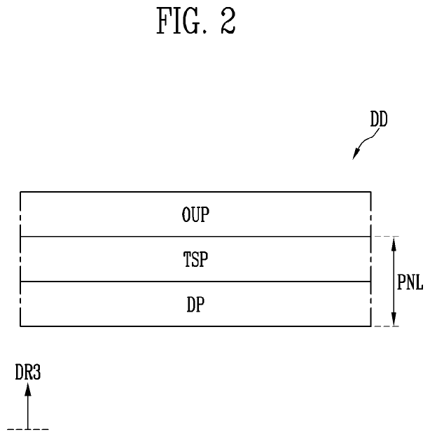

FIG. 1 is a schematic view illustrating an embodiment of a display device in accordance with the disclosure. FIG. 2 is a schematic cross-sectional view illustrating an embodiment of a stacked structure of the display device in accordance with the disclosure.

Referring to FIGS. 1 and 2, the display device DD provide (or emit) light. The display device DD may include a panel PNL and a driving circuit DV for driving the panel PNL. The display device DD may further include an outer part OUP.

The panel PNL may include a display unit DP for displaying an image and a sensor unit TSP capable of sensing a user input (e.g., a touch input). The display unit DP may be designated as a display panel. The sensor unit TSP may be designated as a sensing panel.

The panel PNL may include pixels PXL and sensing electrodes SP. In an embodiment, the pixels PXL may display an image by a display frame period as a unit. The sensing electrodes SP may sense an input (e.g., a touch input) of a user by a sensing frame period as a unit. The sensing frame period and the display frame period may be independent from each other or be different from each other. The sensing frame period and the display frame period may be synchronized with each other or be unsynchronized.

The sensor unit TSP including the sensing electrodes SP may acquire information on a touch input of the user. In an embodiment (e.g., a mutual capacitance type), the sensing electrodes SP may include a first sensing electrode SP1 for providing a first sensing signal and a second sensing electrode SP2 for providing a second sensing signal. In some embodiments, the first sensing electrode SP1 may be a transmitter (“Tx”) pattern electrode, and the second sensing electrode SP2 may be a receiver (“Rx”) pattern electrode. In some embodiments, information on a touch input (or touch event) may mean including the position of a touch which the user is to provide, or the like.

However, the disclosure is not limited thereto. In an embodiment, in an embodiment (e.g., a self-capacitance type), the sensing electrodes SP may be configured with one kind of sensing electrodes without distinguishing the first and second sensing electrodes SP1 and SP2 from each other, for example.

The driving circuit DV may include a display driver DDV for driving the display unit DP and a sensor driver SDV for driving the sensor unit TSP.

The display unit DP may include a display base layer DBSL and pixels PXL provided on the display base layer DBSL. The pixels PXL may be disposed in a display area DA.

The display base layer DBSL (or the display device DD) may include the display area DA in which an image is displayed and a non-display area NDA as an area except the display area DA. In some embodiments, the display area DA may be disposed in a central area of the display unit DP, and the non-display area NDA may be disposed adjacent to the periphery of the display area DA.

The display base layer DBSL may be a base substrate or a base member, which is used to support the display device DD. In some embodiments, the display base layer DBSL may be designated as a “base layer.” The display base layer DBSL may be a rigid substrate including glass. In an alternative embodiment, the display base layer DBSL may be a flexible substrate which is bendable, foldable, rollable, or the like. The display base layer DBSL may include an insulating material including a polymer resin such as polyimide. However, the disclosure is not particularly limited thereto.

Scan lines SL and data lines DL, and the pixels PXL connected to the scan lines SL and the data lines DL are disposed in the display area DA. The pixels PXL may be selected by a scan signal having a turn-on level, which is supplied from the scan lines SL, to be supplied with a data signal from the data lines DL, and emit light with a luminance corresponding to the data signal. Accordingly, an image corresponding to the data signal is displayed in the display area DA. However, in the disclosure, the structure, driving method, or the like of the pixels PXL are not particularly limited.

Various types of lines and/or a built-in circuit, connected to the pixels PXL of the display area DA may be disposed in the non-display area NDA. In an embodiment, a plurality of lines for supplying various power sources and various control signals to the display area DA may be disposed in the non-display area NDA, for example.

The display unit DP may output visual information (e.g., an image). In some embodiments, the type/kind of the display unit DP is not particularly limited. In an embodiment, the display unit DP may be implemented as a self-luminescent display panel such as an organic light-emitting display panel, for example. However, when the display unit DP is implemented as a self-luminescent display panel, each pixel is not necessarily limited to a case where the pixel includes only an organic light-emitting element. In an embodiment, a light-emitting element of each pixel may be configured as an organic light-emitting diode, an inorganic light-emitting diode, a quantum dot/well light-emitting diode, or the like, for example. In an alternative embodiment, the display unit DP may be implemented as a non-light-emitting display panel such as a liquid crystal display panel. When the display unit DP is implemented as a non-light-emitting display panel, the display device DD may additionally include a light source such as a back-light unit.

Hereinafter, for convenience of description, an embodiment in which the display unit DP is implemented as an organic light-emitting display panel will be mainly described.

The sensor unit TSP may include a sensor base layer SBSL and a plurality of sensing electrodes SP formed on the sensor base layer SBSL. The sensing electrodes SP may be disposed in a sensing area SA on the sensor base layer SBSL.

The sensor base layer SBSL (or the display device DD) may include the sensing area SA capable of sensing a touch input or the like and a non-sensing area NSA at the periphery of the sensing area SA. In some embodiments, the sensing area SA may be disposed to overlap with at least one area of the display area DA. In an embodiment, the sensing area SA may be set as an area corresponding to the display area DA (e.g., an area overlapping with the display area DA), and the non-sensing area NSA may be set as an area corresponding to the non-display area NDA (e.g., an area overlapping with the non-display area NDA), for example. When a touch input or the like is provided on the display area DA, the touch input may be detected through the sensor unit TSP.

The sensor base layer SBSL may include at least one insulating layer (e.g., a first insulating layer INS1 (refer to FIG. 4)). In an embodiment, the first insulating layer INS1 for forming the sensor base layer SBSL may be disposed on the display unit DP, to form a base for allowing the sensing electrodes SP to be formed thereon, for example. However, the embodiment of forming the sensing base layer SBSL is not particularly limited.

The sensing area SA is set as an area capable of reacting with a touch input (i.e., an active area of sensors). To this end, sensing electrodes SP for sensing a touch input or the like may be disposed in the sensing area SA.

The sensor unit TSP may acquire information on an input provided from the user. The sensor unit TSP may recognize a touch input. The sensor unit TSP may recognize a touch input by a capacitive sensing type. The sensor unit TSP may sense a touch input by a mutual capacitance type or sense a touch input by a self-capacitance type.

In an embodiment, each of the first sensing electrodes SP1 may extend in a first direction DR1. The first sensing electrodes SP1 may be arranged in a second direction DR2. The second direction DR2 may be different from the first direction DR1. In an embodiment, the second direction DR2 may be a direction orthogonal to the first direction DR1, for example. Each of the first sensing electrodes SP1 may have a form in which first cells having a relatively wide area and first bridge electrodes having a relatively narrow area are connected to each other. The first sensing electrodes SP1 may generally have a diamond shape. However, the shape of the first sensing electrodes SP1 is not particularly limited.

In this specification, the first direction DR1 is a row direction of the pixel PXL, and may be a horizontal direction in FIG. 1. The second direction DR2 is a column direction of the pixel PXL, and may be a perpendicular direction to the horizontal direction FIG. 1 in a plan view. A third direction DR3 may be a display direction of the display device DD or a normal direction of a plane on which the display base layer DBSL is disposed.

In an embodiment, each of the second sensing electrodes SP2 may extend in the second direction DR2. The second sensing electrodes SP2 may be arranged in the first direction DR1. Each of the second sensing electrodes SP2 may have a form in which second cells having a relatively wide area and second bridge electrodes having a relatively narrow area are connected to each other. The second sensing electrodes SP2 may generally have a diamond shape. However, the shape of the second sensing electrodes SP2 is not particularly limited.

In an embodiment, the first sensing electrodes SP1 and the second sensing electrodes SP2 may have the same (e.g., the substantially same) shape. In an embodiment, the first sensing electrodes SP1 as Tx pattern electrodes and the second sensing electrodes SP2 as Rx pattern electrodes may have the substantially same shape, and accordingly, the sensing performance of a touch event in the sensing area SA may be uniformly set, for example.

Sensing lines for electrically connecting the sensing electrodes SP to the sensor driver SDV or the like may be disposed in the non-sensing area NSA of the sensor unit TSP.

The driving circuit DV may include a display driver DDV for driving the display unit DP and a sensor driver SDV for driving the sensor unit TSP.

The display driver DDV is electrically connected to the display unit DP to drive the pixels PXL. The sensor driver SDV is electrically connected to the sensor unit TSP to drive the sensor unit TSP.

The outer part OUP may be roughly disposed at an outer portion of the display device DD. The outer part OUP may be disposed on the sensor unit TSP. Light provided from the display unit DP may be output to the outside while passing through the outer part OUP.

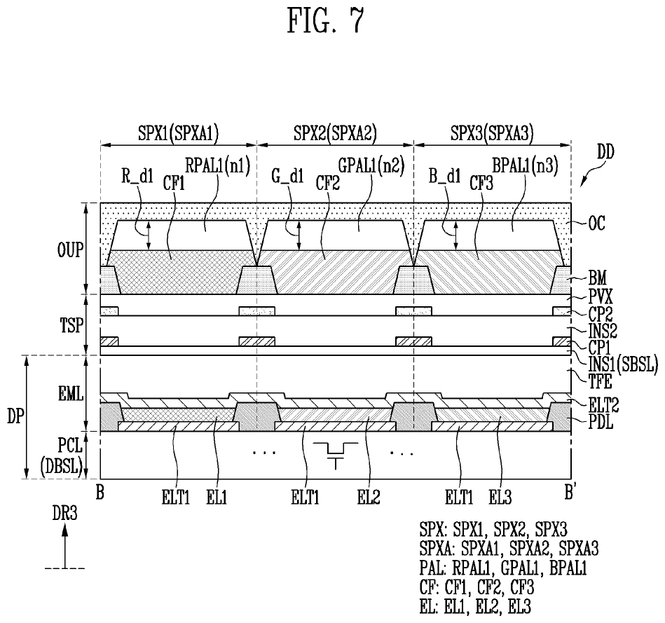

The outer part OUP may protect internal components of the display device DD from external influence. Also, the outer part OUP may include a refractive layer PAL (refer to FIG. 7) capable of improving external visibility by implementing a phase control structure. This will be described in detail later.

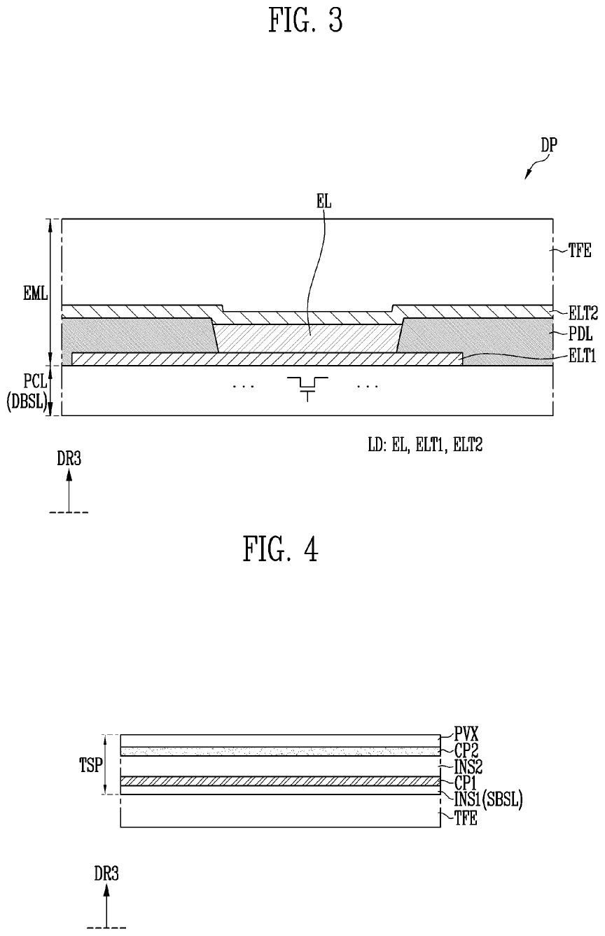

Next, an embodiment of the display unit DP will be described with reference to FIG. 3. FIG. 3 is a schematic cross-sectional view illustrating an embodiment of a display unit in accordance with the disclosure.

Referring to FIG. 3, the display unit DP may include a pixel circuit layer PCL and a light-emitting element layer EML.

The pixel circuit layer PCL may include a pixel circuit for driving light-emitting elements LD. The pixel circuit layer PCL may include a display base layer DBSL, conductive layers for forming pixel circuits, and insulating layers disposed between the conductive layers.

The pixel circuit may include a thin film transistor. The pixel circuit may include a driving transistor. The pixel circuit may be electrically connected to the light-emitting elements LD to provide an electrical signal for allowing the light-emitting elements LD to emit light.

The light-emitting element layer EML may be disposed on the pixel circuit layer PCL. In some embodiments, the light-emitting element layer EML may include a light-emitting element LD, a pixel defining layer PDL, and an encapsulation layer TFE.

The light-emitting element LD may be disposed on the pixel circuit layer PCL. In some embodiments, the light-emitting element LD may include a first electrode ELT1, a light-emitting layer EL, and a second electrode ELT2. In some embodiments, the light-emitting layer EL may be disposed in an area defined by the pixel defining layer PDL. The pixel defining layer PDL may be adjacent to the periphery of the light-emitting layer EL. One surface of the light-emitting layer EL may be electrically connected to the first electrode ELT1, and the other surface of the light-emitting layer EL may be electrically connected to the second electrode ELT2.

The first electrode ELT1 may be an anode electrode with respect to the light-emitting layer EL, and the second electrode ELT2 may be a common electrode (or cathode electrode) with respect to the light-emitting layer EL. In an embodiment, the first electrode ELT1 and the second electrode ELT2 may include a conductive material. In an embodiment, the first electrode ELT1 may include a conductive material having reflexibility, and the second electrode ELT2 may include a transparent conductive material. However, the disclosure is not limited thereto.

The light-emitting layer EL may have a multi-layer thin film structure including a light generation layer. The light-emitting layer EL may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. The light-emitting layer EL may release light, based on an electrical signal provided from the first electrode ELT1 and the second electrode ELT2.

The pixel defining layer PDL may be disposed on the pixel circuit layer PCL, to define a position at which the light-emitting layer EL is arranged. The pixel defining layer PDL may include an organic material. In some embodiments, the pixel defining layer PDL may include at least one selected from the group including acrylic resin, epoxy resin, phenolic resin, polyamide resin, and polyimide resin. However, the disclosure is not limited thereto. In some embodiments, the pixel defining layer PDL may include an inorganic material.

The encapsulation layer TFE may be disposed over the second electrode ELT2. The encapsulation layer TFE may cancel a step difference generated by the light-emitting element LD and the pixel defining layer PDL. The encapsulation layer TFE may include a plurality of insulating layers covering the light-emitting element LD. In some embodiments, the encapsulation layer TFE may have a structure in which an inorganic layer and an organic layer are alternately stacked. In some embodiments, the encapsulation layer TFE may be a thin film encapsulation layer.

Next, an embodiment of the sensor unit TSP will be described with reference to FIG. 4. FIG. 4 is a schematic cross-sectional view illustrating an embodiment of a sensing unit in accordance with the disclosure.

Referring to FIG. 4, the sensor unit TSP may be disposed on the encapsulation layer TFE. The sensor unit TSP may include a first insulating layer INS1, a first conductive pattern CP1, a second insulating layer INS2, a second conductive pattern CP2, and a protective layer PVX.

In an embodiment, the first conductive pattern CP1 and the second conductive pattern CP2 are patterned at one position, to form sensing electrodes SP. In an embodiment, a portion of each of the first conductive pattern CP1 and the second conductive pattern CP2 may constitute a first sensing electrode SP1, and a portion of the second conductive pattern CP2 may constitute a second sensing electrode SP2, for example. However, the disclosure is not limited thereto.

The first insulating layer INS1 may be disposed on the encapsulation layer TFE. The first insulating layer INS1 may form a sensor base layer SBSL, thereby providing an area in which the first conductive pattern CP1, the second insulating layer INS2, the second conductive pattern CP2, and the protective layer PVX are disposed.

The first conductive pattern CP1 may be disposed on the first insulating layer INS1. The second conductive pattern CP2 may be disposed on the second insulating layer INS2. The first conductive pattern CP1 and the second conductive pattern CP2 may be spaced apart from each other with the second insulating layer INS2 interposed therebetween.

The first conductive pattern CP1 and the second conductive pattern CP2 may include a single- or multi-layer metal layer. The first conductive pattern CP1 and the second conductive pattern CP2 may include at least one of various metal materials including gold (Au), silver (Ag), aluminum (Al), molybdenum (Mo), chromium (Cr), titanium (Ti), nickel (Ni), neodymium (Nd), copper (Cu), platinum (Pt), or the like, or alloys thereof. In some embodiments, the first conductive pattern CP1 and the second conductive pattern CP2 may include at least one of various transparent conductive materials including one of silver nano wire (AgNW), Indium Tin Oxide (“ITO”), Indium Zinc Oxide (“IZO”), Indium Gallium Zinc Oxide (“IGZO”), Antimony Zinc Oxide (“AZO”), Indium Tin Zinc Oxide (“ITZO”), Zinc Oxide (ZnO), Tin Oxide (SnO₂), carbon nano tube, graphene, or the like.

The second insulating layer INS2 may be disposed on the first conductive pattern CP1. The second insulating layer INS2 may be interposed between the first conductive pattern CP1 and the second conductive pattern CP2. The protective layer PVX may be disposed on the second conductive pattern CP2.

The first insulating layer INS1 and the second insulating layer INS2 may include an inorganic material. The inorganic material may include at least one selected from the group including silicon nitride (SiNₓ), silicon oxide (SiOₓ), silicon oxynitride (SiOₓN_{y}), and aluminum oxide (AlOₓ). The protective layer PVX may include an organic material. The organic material may include at least one of acryl-based resin, methacryl-based resin, polyisoprene, vinyl-based resin, epoxy-based resin, urethane-based resin, cellulose-based resin, siloxane-based resin, polyimide-based resin, polyamide-based resin, and perylene-based resin. However, the disclosure is not limited thereto.

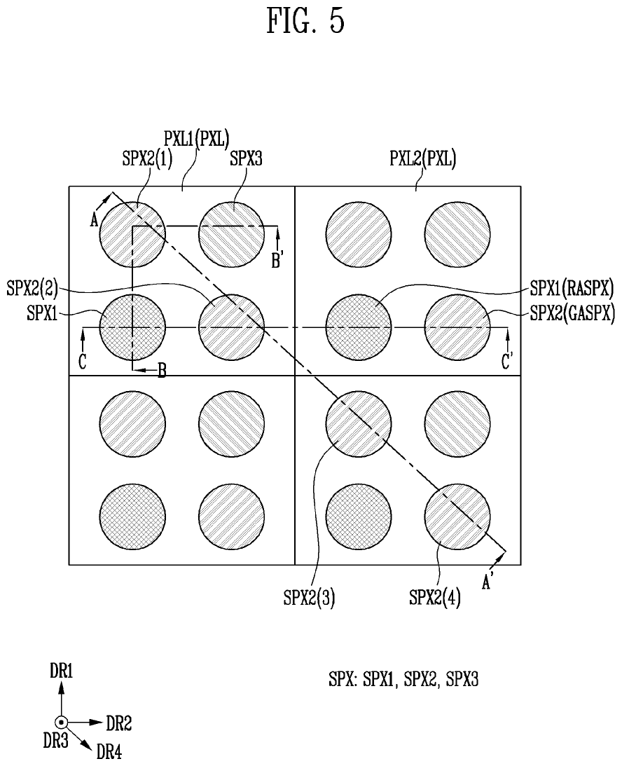

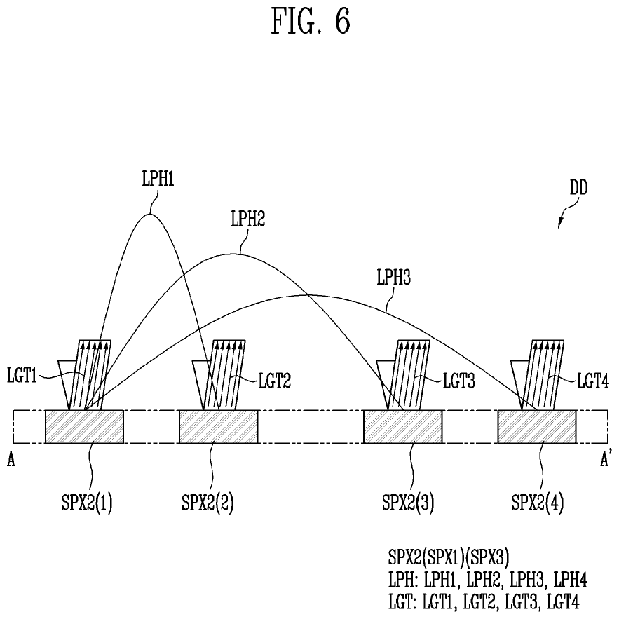

Next, a structure of sub-pixels SPX of the display device DD and an external light reflection phenomenon associated therewith will be described with reference to FIGS. 5 and 6.

FIG. 5 is a schematic view illustrating an embodiment of a pixel in accordance with the disclosure. FIG. 6 is a schematic view illustrating a diffraction pattern of light applied to the display device from the outside of the display device. The diffraction pattern LPH may be a schematic pattern representing an intensity of light when reflected lights LGT according to external light reflection are interfered with each other.

Referring to FIG. 5, the pixel PXL may include sub-pixels SPX. The sub-pixels SPX may include a first sub-pixel SPX1, a second sub-pixel SPX2, and a third sub-pixel SPX3.

In some embodiments, the sub-pixels SPX may be arranged according to the various structures. In an embodiment, pixels PXL (or sub-pixels SPX) may be arranged according to a PENTILE™ structure. Accordingly, one pixel PXL may include one first sub-pixel SPX1, two second sub-pixel SPX2, and one third sub-pixel SPX3, for example. In an alternative embodiment, pixels PXL (or sub-pixels SPX) may be arranged according to a stripe structure or the like. However, the disclosure is not necessarily limited thereto, and the number of sub-pixels SPX included in one pixel PXL is not particularly limited.

Hereinafter, for convenience of description, an embodiment in which the pixel PXL (or the sub-pixels SPX) includes one first sub-pixel SPX1, two second sub-pixels SPX2, and one third sub-pixel SPX3 will be mainly described.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of about 600 nanometers (nm) to about 750 nm, the green wavelength band may be a wavelength band of about 480 nm to about 560 nm, and the blue wavelength band may be a wavelength band of about 370 nm to about 460 nm. However, the embodiment of the disclosure is not limited thereto.

Each of the sub-pixels SPX may include a light-emitting element LD (refer to FIG. 3) configured to emit light.

In some embodiments, sub-pixels SPX emitting light of the same color may be adjacent to each other with a sub-pixel SPX emitting light of another color, which is interposed therebetween.

In an embodiment, first sub-pixels SPX1 may be adjacent to each other with a second sub-pixel SPX2 interposed therebetween in the first direction DR1 or the second direction DR2, for example. First sub-pixels SPX1 may be adjacent to each other with a third sub-pixel SPX3 interposed therebetween in a fourth direction DR4 as a direction (e.g., a right lower diagonal direction with respect to the first direction DR1) different from the first direction DR1 and the second direction DR2. In some embodiments, a first sub-pixel SPX1 of a first pixel PXL1 may be adjacent to a first sub-pixel SPX1 of a second pixel PXL2 with a second sub-pixel SPX2 interposed therebetween in the second direction DR2.

Second sub-pixels SPX2 may be adjacent to each other with a first sub-pixel SPX1 or a third sub-pixel SPX3, which is interposed therebetween, in the first direction DR1, or be adjacent to each other with a first sub-pixel SPX1 or a third sub-pixel SPX3, which is interposed therebetween, in the second direction DR2.

Third sub-pixels SPX3 may be adjacent to each other with a second sub-pixel SPX2 interposed therebetween in the first direction DR1 or the second direction DR2. Third sub-pixels SPX may be adjacent to each other with a first sub-pixel SPX1 interposed therebetween in a direction (e.g., the fourth direction DR4) different from the first direction DR1 and the second direction DR2.

In some embodiments, sub-pixels SPX emitting light of the same color may be directly adjacent to each other. The sub-pixels SPX emitting light of the same color may be directly adjacent to each other with any sub-pixel emitting light of another color, which is not interposed therebetween.

In an embodiment, second sub-pixels SPX2 may be directly adjacent to each other in the fourth direction DR4, for example. The second sub-pixels SPX2 may be disposed in a first area 1, a second area 2, a third area 3, and a fourth area 4, which are adjacent to each other. The first area 1, the second area 2, the third area 3, and the fourth area 4 may be sequentially disposed along the fourth direction DR4. The first area 1, the second area 2, the third area 3, and the fourth area 4 may be directly adjacent to each other.

Sub-pixels SPX emitting light of the same color may be disposed in the first area 1, the second area 2, the third area 3, and the fourth area 4. In FIG. 5, it is illustrated that second sub-pixels SPX2 are respectively disposed in the first area 1, the second area 2, the third area 3, and the fourth area 4. Although a case where the second sub-pixels SPX2 are directly adjacent to each other in the fourth direction DR4 has been illustrated in FIG. 5, the disclosure is not limited thereto. First sub-pixels SPX1 or third sub-pixels SPX3 may be disposed adjacent to each other in the fourth direction DR4.

Hereinafter, for convenience description, the first sub-pixel SPX1 of the first pixel PXL1 is continuously designated as a “first sub-pixel SPX1,” and a second sub-pixel SPX2 of the first pixel PXL1 is continuously designated as a “second sub-pixel SPX2.” The first sub-pixel SPX1 of the second pixel PXL2 as another pixel adjacent to the first pixel PXL1 is defined as a first adjacent sub-pixel RASPX, and a second sub-pixel SPX2 of the second pixel PXL2 is defined as a second adjacent sub-pixel GASPX.

Hereinafter, an external light reflection phenomenon of the display device DD will be described with reference to FIG. 6 in conjunction with FIG. 5.

Referring to FIG. 6, the first area 1, the second area 2, the third area 3, and the fourth area 4 in which adjacent second sub-pixels SPX2 are disposed may be disposed on the same plane.

Each of the second sub-pixels SPX2 may be respectively disposed in the first area 1, the second area 2, the third area 3, and the fourth area 4, which are disposed on the same plane.

External light may be applied to the inside of the display device DD. At least a portion of the external light may be reflected on the light-emitting layer EL disposed in the light-emitting element LD while being transmitted through the outer part OUP and the sensor unit TSP of the display device DD. Reflected light LGT defined inside the display device DD may include at least a portion of the external light reflected in the light-emitting element LD. The reflected light LGT may include first reflected light LGT1, second reflected light LGT2, third reflected light LGT3, and fourth reflected light LGT4.

The first reflected light LGT1 may be light reflected in the first area 1. The second reflected light LGT2 may be light reflected in the second area 2. The third reflected light LGT3 may be light reflected in the third area 3. The fourth reflected light LGT4 may be light reflected in the fourth area 4. As the first to fourth areas 1 to 4 are disposed on the same plane, at least some of the first reflected light LGT1, the second reflected light LGT2, the third reflected light LGT3, and the fourth reflected light LGT4 may have the same phase.

At least some having the same phase among the first reflected light LGT1, the second reflected light LGT2, the third reflected light LGT3, and the fourth reflected light LGT4 may be constructively interfered with each other, to form a diffraction pattern LPH. Some reflected lights LGT1 to LGT4 having the same phase among the first reflected light LGT1, the second reflected light LGT2, the third reflected light LGT3, and the fourth reflected light LGT4 may overlap with each other to form overlapping light, and the overlapping light may form a diffraction pattern LPH. The overlapping light may have a predetermined light intensity according to the diffraction pattern LPH. The diffraction pattern LPH shown in FIG. 6 illustrates an intensity of light according to the overlapping light.

In FIG. 6, for convenience, it is only illustrated that the first reflected light LGT1 forms each of the second to fourth reflected lights LGT2 to LGT4 and the diffraction pattern LPH. However, the disclosure is not limited thereto. In an embodiment, the second reflected light LGT2 may form the third or fourth reflected light LGT3 or LGT4 and the diffraction pattern LPH, and the third reflected light LGT3 may form the fourth reflected light LGT4 and the diffraction pattern LPH, for example.

Hereinafter, for convenience of description, a case where the first reflected light LGT1 forms each of the second to fourth reflected lights LGT2 to LGT4 and the diffraction pattern LPH will be mainly described. The diffraction pattern LPH schematically illustrates an intensity of light for each area of overlapping reflected lights LGT when the reflected lights LGT overlap with each other.

Lights having the same phase among the first and second reflected lights LGT1 and LGT2 may be interfered with each other to form a first diffraction pattern LPH1. Lights having the same phase among the first and third reflected lights LGT1 and LGT3 may be interfered with each other to form a second diffraction pattern LPH2. Lights having the same phase among the first and fourth reflected lights LGT1 and LGT4 may be interfered with each other to form a third diffraction pattern LPH3.

Experimentally, as lights reflected or diffracted in two areas may be constructively interfered with each other, interfered light may have a highest intensity at a central point of the two areas. In an embodiment, the first diffraction pattern LPH1 may have a peak (e.g., the height of a highest point in the third direction DR3 in the diffraction pattern LPH) at a central portion of the first area 1 and the second area 2, for example.

In this specification, the “peak” of the diffraction pattern LPH is defined as a “highest intensity of light, which the diffraction pattern LPH has.” The peak of the diffraction pattern LPH may correspond to a point at which the diffraction pattern LPH has a highest intensity of light when reflected lights LGT forming the diffraction pattern LPH overlap with each other. The second diffraction pattern LPH2 may have a peak at a central portion of the first area 1 and the third area 3. The third diffraction pattern LPH3 may have a peak at a central portion of the first area 1 and the fourth area 4.

Also, experimentally, the diffraction pattern LPH of reflected light LGT may have a higher peak as the intensity of interfered reflected light LGT becomes higher (e.g., as the vibration frequency or energy of the reflected light LGT becomes higher) and as the distance between the reflected light LGT and the interfered reflected light LGT becomes shorter.

In an embodiment, since, as shown in FIG. 6, a distance between the first area 1 and the second area 2 is relatively shorter than a distance between the first area 1 and the third area 3, a peak of the first diffraction pattern LPH1 formed by the first reflected light LGT1 and the second reflected light LGT2 may be higher than a peak of the second diffraction pattern LPH2 formed by the first reflected light LGT1 and the third reflected light LGT3, for example.

In addition, the diffraction pattern LPH of reflected light LGT may have a higher peak as the number of adjacent sub-pixels SPX between which distance is short in sub-pixels SPX emitting light of the same color becomes larger. In an embodiment, a display device DD having a relatively high resolution may include a relatively large number of sub-pixels SPX emitting light of the same color, as compared with a display device DD having a relatively low resolution, and a peak of a diffraction pattern LPH in the display device DD having the relatively high resolution may be higher than a peak of a diffraction pattern LPH in the display device DD having the relatively low resolution, for example.

As the peak of the diffraction pattern LPH becomes higher, light which is applied to the display device DD from the outside of the display device DD and then reflected may be intensively (or more clearly) viewed by a user. In an embodiment, an image formed by the peak of the first diffraction pattern LPH1 may be more intensively viewed than an image formed by the peak of the second diffraction pattern LPH2, for example.

According to a conventional display structure, as reflected light LGT which is applied from the outside and then reflected is viewed with different intensities, a multi-image phenomenon may occur, in which two or more images are viewed. As the multi-phase phenomenon occurred, an image was formed even at the periphery of a light source (e.g., a surface light source, a point light source, or the like) (e.g., an outer area of the light source) by external light in observation of the light source in a conventional display. According to the conventional display structure, the multi-image phenomenon frequently occurred, and accordingly, a risk existed that the external visibility of the display would be reduced. However, according to the display device DD in accordance with the disclosure, a risk that the multi-image phenomenon will occur may be reduced, and the external visibility may be improved.

Hereinafter, a structural feature including an external visibility improvement structure as a stacked structure of a display device DD in an embodiment of the disclosure and an external visibility improvement principle will be described with reference to FIGS. 7 to 13. In FIGS. 7 to 13, descriptions of portions overlapping with those described above will be simplified or will not be repeated.

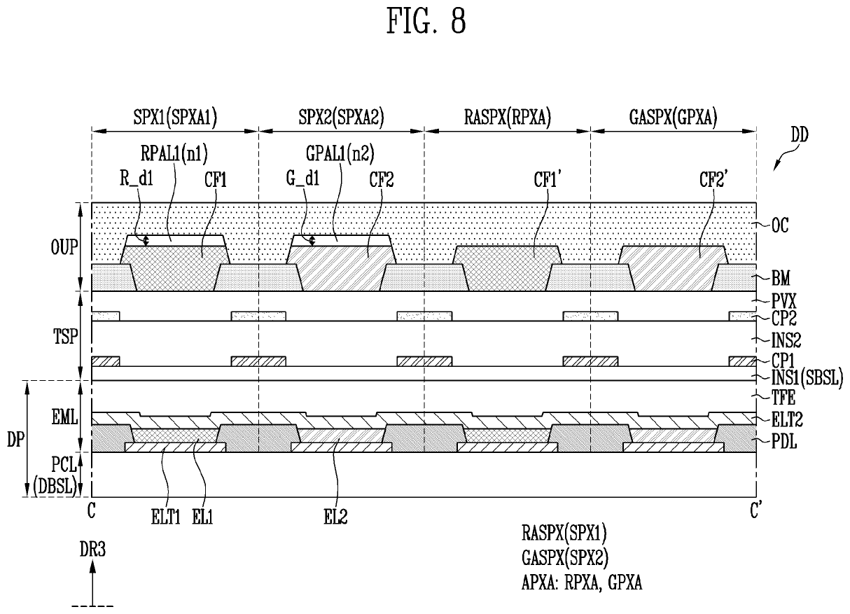

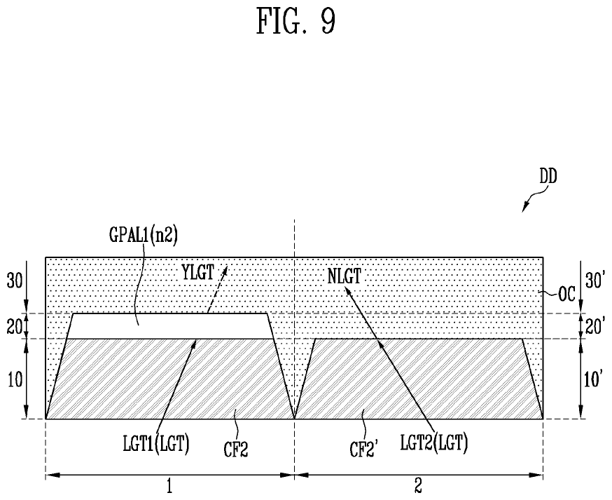

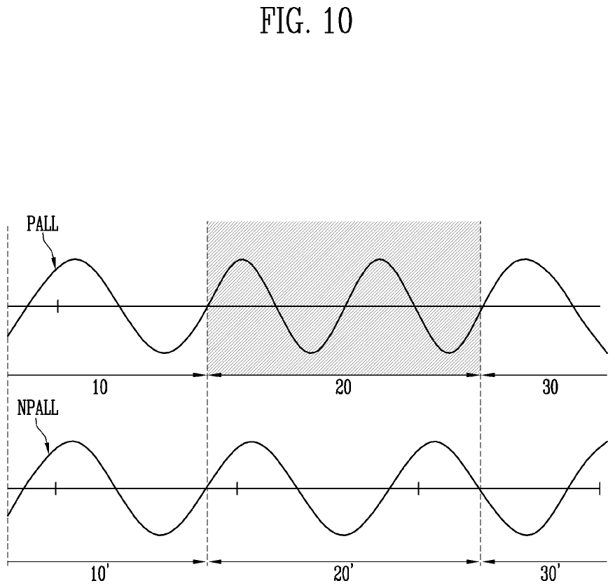

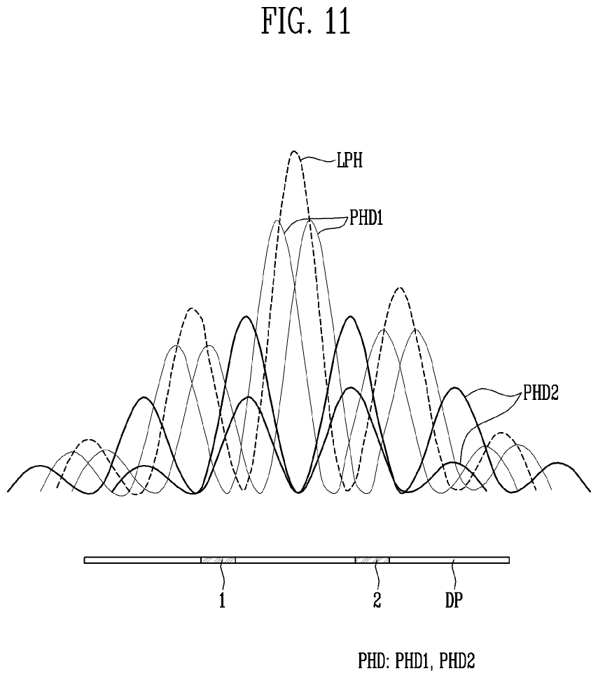

FIGS. 7 and 8 are schematic cross-sectional views of a display device in accordance with a first embodiment of the disclosure. FIG. 7 is a schematic cross-sectional view of the display device DD taken along line B-B′ shown in FIG. 5. FIG. 8 is a schematic cross-sectional view of the display device DD taken along line C-C′ shown in FIG. 5. FIGS. 9 and 10 are schematic views illustrating an embodiment of a phase change of reflected light of the display device in accordance with the disclosure. FIG. 9 is a schematic view illustrating a transmission area of reflective light LGT in a second sub-pixel SPX2 and a second adjacent sub-pixel GASPX, which are shown in FIG. 8. FIG. 9 illustrates reflected light LGT reflected in the first area 1 and the second area 2, which are shown in FIG. 6. FIG. 10 is a schematic view illustrating a first wave PALL of light transmitted through a refractive layer PAL and a second wave NPALL of light not transmitted through the refractive layer PA in accordance with the disclosure. FIG. 11 is a schematic view illustrating an embodiment of a diffraction pattern of light transmitted through a refractive layer of the display device in accordance with the disclosure. FIG. 11 is a schematic view illustrating an embodiment of comparison of the diffraction pattern LPH shown in FIG. 6 with a change pattern PHD of light transmitted through the refractive layer PAL of the display device DD in accordance with the disclosure.

First, a stacked structure of the display device in accordance with the first embodiment of the disclosure will be described with reference to FIGS. 7 and 8. In the first embodiment, some of sub-pixels SPX emitting light of the same color may include a refractive layer PAL, and at least others of the sub-pixels SPX may not include the refractive layer PAL.

The display device DD may include sub-pixels SPX1, SPX2, and SPX3 each forming a sub-pixel area SPXA. The sub-pixel areas SPXA may include a first sub-pixel area SPXA1 as an area formed by the first sub-pixel SPX1, in which light of a first color is emitted, a second sub-pixel area SPXA2 as an area formed by the second sub-pixel SPX2, in which light of a second color is emitted, and a third sub-pixel area SPXA3 as an area formed by the third sub-pixel SPX3, in which light of a third color is emitted.

The display device DD in the embodiment of the disclosure may include first to third light-emitting layers EL1, EL2, and EL3 emitting lights of different colors. However, the disclosure is not limited thereto, and therefore, the first to third light-emitting layers EL1, EL2, and EL3 may emit light of the same color.

The first light-emitting layer EL1 may form a first light-emitting element emitting light of the first color, the second light-emitting layer EL2 may form a second light-emitting element emitting light of the second color, and the third light-emitting layer EL3 may form a third light-emitting element emitting light of the third color. However, the disclosure is not limited thereto. The first to third light-emitting layers EL1 to EL3 may emit light of the same color.

In an embodiment, a first conductive pattern CP1 and a second conductive pattern CP2 in a sensor unit TSP may be disposed in different layers, to form a structure of sensing electrodes SP.

An outer part OUP may be disposed on the sensor unit TSP. The outer part OUP may be disposed outward of the first conductive pattern CP1 and the second conductive pattern CP2, which form the sensing electrodes SP.

The outer part OUP may include light-blocking members BM, a color filter CF, a refractive layer PAL, and an overcoat layer OC.

The light-blocking member BM may be disposed on the sensor unit TSP. The light-blocking member BM may overlap with a pixel defining layer PDL in a plan view. The light-blocking member BM may have a mesh pattern or a mesh structure like first and second sensing electrodes SP1 and SP2, or include an opening corresponding to an opening defined by the pixel defining layer PDL. The light-blocking member BM may not overlap with the opening defined by the pixel defining layer PDL.

The light-blocking member BM may block (e.g., absorb) at least a portion of external light applied to the inside of the display device from the outside. The light-blocking member BM may have a substantially opaque color. In an embodiment, the light-blocking member BM may further include a light-blocking material to absorb light, for example. The light block material may include carbon black, titanium oxynitride, titanium black, phenylene black, aniline black, cyanine black, nigrosin acid black, black resin, or the like.

The color filter CF may be disposed between the light-blocking members BM. The color filters CF may be disposed in an opening area defined by the light-blocking members BM.

The color filter CF may include a first color filter CF1, a second color filter CF2, and a third color filter CF3. The first color filter CF1, the second color filter CF2, and the third color filter CF3 may be disposed in the same layer.

The first color filter CF1 may be disposed above the first light-emitting layer EL1. The first color filter CF1 may overlap with the first light-emitting layer EL1. The first color filter CF1 may be disposed in the first sub-pixel area SPXA1 emitting first light. The second color filter CF2 may be disposed above the second light-emitting layer EL2. The second color filter CF2 may overlap with the second light-emitting layer EL2. The second color filter CF2 may be disposed in the second sub-pixel area SPXA2 emitting second light. The third color filter CF3 may be disposed above the third light-emitting layer EL3. The third color filter CF3 may overlap with the third light-emitting layer EL3. The third color filter CF3 may be disposed in the third sub-pixel area SPXA3 emitting third light.

Light emitted in the first light-emitting layer EL1 may be released (or emitted) as light of the first color while passing through the first color filter CF1. Light emitted in the second light-emitting layer EL2 may be released (or emitted) as light of the second color while passing through the second color filter CF2. Light emitted in the third light-emitting layer EL3 may be released (or emitted) as light of the third color while passing through the third color filter CF3.

The color filter CF may allow light in a predetermined wavelength band among reflected lights LGT caused by external light to be transmitted therethrough, in addition to light emitted in a light-emitting layer EL. In an embodiment, the first color filter CF1 may allow light in a red wavelength band to be transmitted therethrough, the second color filter CF2 may allow light in a green wavelength band to be transmitted therethrough, and the third color filter CF3 may allow light in a blue wavelength band to be transmitted therethrough, for example. Accordingly, at least a portion of light transmitted through the color filter CF among the reflected lights LGT caused by the external light may have a different spectrum (e.g., a wavelength of light) as compared with the conventional display structure in which the color filter CF is not disposed.

The refractive layer PAL may be disposed on the color filter CF. The refractive layer PAL may overlap with the color filter CF in a plan view. One surface of the refractive layer PAL may contact one surface of the color filter CF. The refractive layer PAL may be physically spaced apart from the light-blocking member BM.

The refractive layer PAL may control the phase of reflected light LGT transmitted through the refractive layer PAL. In the display device DD in accordance with the disclosure, the refractive layer PAL is disposed on the color filter CF, so that the reflected light LGT transmitted through the refractive layer PAL may have a different phase as compared with when the reflected light LGT is not transmitted through the refractive layer PAL. Thus, in the display device DD in accordance with the disclosure, at least a portion of the reflected light LGT has a different phase, thereby reducing a phenomenon in which reflected lights LGT are constructively interfered with each other. This will be described in detail later with reference to FIG. 9.

The refractive layer PAL may be a relatively high refractive layer having a refractive index relatively greater than a refractive index of the color filter and the overcoat layer OC disposed over the refractive layer PAL. In an embodiment, the refractive index of the refractive layer PAL may be about 1.5 or more, and the refractive index of the color filter CF and the overcoat layer OC may be less than about 1.5, for example. However, the disclosure is not limited thereto.

In some embodiments, the refractive layer PAL may include an organic material or an inorganic material.

The organic material of the refractive layer PAL may include at least one of various organic materials such PEDOT, TPD, m-MTDATA, o-MTDAB, m-MTDAB, p-MTDAB, BPPM, TPBI, and TAZ. However, the disclosure is not necessarily limited thereto. The refractive layer PAL may include various organic materials having a refractive index of 1.5 or more. The inorganic material of the refractive layer PAL may include at least one of various inorganic materials such as copper (Cu), iodine (I), thallium (Tl), silver (Ag), cadmium (Cd), mercury (Hg), tin (Sn), lead (Pb), zinc (Zn), and iron (Fe), or a metal oxide such as titanium oxide (TiOₓ), tantalum oxide (TaOₓ), hafnium oxide (HfOₓ) or zirconium oxide (ZrOₓ).

The refractive layer PAL may include a first refractive layer RPAL1, a second refractive layer GPAL1, and a third refractive layer BPAL1.

The first refractive layer RPAL1 may be disposed in the first sub-pixel area SPXA1 emitting light of the first color. The first refractive layer RPAL1 may be disposed on the first color filter CF1. One surface of the first refractive layer RPAL1 may contact one surface of the first color filter CF1. The one surface of the first refractive layer RPAL1 may contact a top surface of the first color filter CF1.

The second refractive layer GPAL1 may be disposed in the second sub-pixel area SPXA2 emitting light of the second color. The second refractive layer GPAL1 may be disposed on the second color filter CF2. One surface of the second refractive layer GPAL1 may contact one surface of the second color filter CF2. The one surface of the second refractive layer GPAL1 may contact a top surface of the second color filter CF2.

The third refractive layer BPAL1 may be disposed in the third sub-pixel area SPXA3 emitting light of the third color. The third refractive layer BPAL1 may be disposed on the third color filter CF3. One surface of the third refractive layer BPAL1 may contact one surface of the third color filter CF3. The one surface of the third refractive layer BPAL1 may contact a top surface of the third color filter CF3.

The first refractive layer RPAL1 may have a first refractive index n1. The second refractive layer GPAL1 may have a second refractive index n2. The third refractive layer BPAL1 may have third refractive index n3.

The first refractive index n1, the second refractive index n2, and the third refractive index n3 may be the same. In an embodiment, the first refractive layer RPAL1, the second refractive layer GPAL1, and the third refractive layer BPAL1 may include the same material, and the first to third refractive indices n1 to n3 may be the same, for example.

The first refractive index n1, the second refractive index n2, and the third refractive index n3 may be different from one another. In an embodiment, the first refractive layer RPAL1, the second refractive layer GPAL1, and the third refractive layer BPAL1 may include different materials from each other, and the first to third refractive indices n1 to n3 may be different from one another, for example.

The first refractive layer RPAL1 may have a first thickness R_d1. The second refractive layer GPAL1 may have a second thickness G_d1. The third refractive layer BPAL1 may have a third thickness B_d1.

The first thickness R_d1, the second thickness G_d1, and the third thickness B_d1 may be the same. The first thickness R_d1, the second thickness G_d1, and the third thickness B_d1 may be different from one another. In some embodiments, the first thickness R_d1 may be greater than the second thickness G_d1, and the second thickness G_d1 may be greater than the third thickness B_d1. However, the disclosure is not limited thereto.

The overcoat layer OC may be disposed over the light-blocking member BM and the color filter CF. The overcoat layer OC may cover an entirety of the light-blocking member BM, the color filter CF, and the refractive layer PAL. The overcoat layer OC may cancel a step difference generated by the light-blocking member BM, the color filter CF, and the refractive layer PAL. The overcoat layer OC may prevent infiltration of moisture or air.

The overcoat layer OC may include an organic material such as acrylic resin, epoxy resin, phenolic resin, polyamide resin, polyimide resin, polyester resin, poly-phenylene ether resin, poly-phenylene sulfide resin, or benzocyclobutene. However, the disclosure is not necessarily limited thereto, and the overcoat layer OC may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

Referring to FIG. 8, at least a portion of first sub-pixels SPX1 may not include the first refractive layer RPAL1. At least a portion of second sub-pixels SPX2 may not include the second refractive layer GPAL1.

Although only the first and second sub-pixels SPX1 and SPX2 are illustrated in FIG. 8, a structural feature corresponding to the first sub-pixel SPX1 and the second sub-pixel SPX2 may be applied to the third sub-pixel SPX3. In an embodiment, at least a portion of third sub-pixels SPX3 may not include the third refractive layer BPAL1, for example.

Hereinafter, FIG. 8 in which the first sub-pixel SPX1 and the second sub-pixel SPX2 are illustrated will be mainly described. In FIG. 8, descriptions of portions overlapping with those described above will be simplified or will not be repeated.

The display device DD may include a first sub-pixel area SPXA1 in which the first sub-pixel SPX1 is disposed, a second sub-pixel area SPXA2 in which the second sub-pixel SPX2 is disposed, and an adjacent sub-pixel area APXA. The adjacent sub-pixel area APXA may be an area adjacent to the sub-pixel area SPXA (refer to FIG. 7). The adjacent sub-pixel area APXA may include a first adjacent sub-pixel area RPXA in which a first adjacent sub-pixel RASPX is disposed and a second adjacent sub-pixel area GPXA in which a second adjacent sub-pixel GASPX is disposed.

The first adjacent sub-pixel area RPXA may be adjacent to the first sub-pixel area SPXA1 with the second sub-pixel SPX2 interposed therebetween. The first adjacent sub-pixel area RPXA may be an area in which the first adjacent sub-pixel RASPX adjacent to the first sub-pixel SPX1 with the second sub-pixel SPX2 interposed therebetween is disposed. The first adjacent sub-pixel area RPXA may be an area emitting light of the same color as the first sub-pixel area SPXA1.

The first adjacent sub-pixel area RPXA may be an area in which a first adjacent color filter CF1′ is disposed. In this specification, for convenience of description, a color filter disposed in the first adjacent sub-pixel area RPXA is defined as the first adjacent color filter CF1′ so as to distinguish the color filter from the first color filter CF1 disposed in the first sub-pixel area SPXA1. The first adjacent color filter CF1′ may be disposed in the same layer as the first color filter CF1. The first adjacent color filter CF1′ may be disposed between light-blocking members BM disposed in the first adjacent sub-pixel area RPXA. The first adjacent color filter CF1′ may be disposed on a protective layer PVX disposed in the first adjacent sub-pixel area RPXA.

The first adjacent sub-pixel area RPXA may be an area in which the first refractive layer RPAL1 is not disposed. The first refractive layer RPAL1 may not overlap with the first adjacent color filter CF1′ in a plan view. As a layer corresponding to the first refractive layer RPAL1 (e.g., including the same material) is not disposed in the first adjacent sub-pixel area RPXA, a top surface of the first adjacent color filter CF1′ may contact the overcoat layer OC. The overcoat layer OC may cover an entirety of the first adjacent color filter CF1′. The top surface of the first adjacent color filter CF1′ may be entirely adjacent directly to the overcoat layer OC. As compared with this, the top surface of the first color filter CF1 may not contact the overcoat layer OC. In this specification, an upper direction may be a direction becoming distant from the display base layer DBSL in the third direction DR3 (e.g., the opposite direction of gravity).

The first refractive layer RPAL1 may not overlap with the first adjacent color filter CF1′ in a plan view. The one surface of the first refractive layer RPAL1 may not in contact with one surface of the first adjacent color filter CF1′.

As the first refractive layer RPAL1 is disposed on the first color filter CF1 and the layer corresponding to the first refractive layer RPAL1 (e.g., including the same material) is not disposed on the first adjacent color filter CF1′, a refractive index difference between the first color filter CF1 and the first refractive layer RPAL1 may be different from a refractive index difference between the first adjacent color filter CF1′ and a layer (e.g., the overcoat layer OC) disposed directly on the first adjacent color filter CF1′.

The second adjacent sub-pixel area GPXA may be adjacent to the second sub-pixel area SPXA2 with the first sub-pixel SPX1 interposed therebetween. The second adjacent sub-pixel area GPXA may be an area in which the second adjacent sub-pixel GASPX adjacent to the second sub-pixel SPX2 with the first sub-pixel SPX1 interposed therebetween is disposed. The second adjacent sub-pixel area GPXA may be an area emitting light of the same color as the second sub-pixel area SPXA2.

The second adjacent sub-pixel area GPXA may be an area in which a second adjacent color filter CF2′ is disposed. In this specification, for convenience of description, a color filter disposed in the second adjacent sub-pixel area GPXA is defined as the second adjacent color filter CF2′ so as to distinguish the color filter from the second color filter CF2 disposed in the second sub-pixel area SPXA2. The second adjacent color filter CF2′ may be disposed in the same layer as the second color filter CF2. The second adjacent color filter CF2′ may be disposed between light-blocking members BM disposed in the second adjacent sub-pixel area GRPXA. The second adjacent color filter CF2′ may be disposed on the protective layer PVX disposed in the second adjacent sub-pixel area GPXA.

The second adjacent sub-pixel area GPXA may be an area in which the second refractive layer GPAL1 is not disposed. The second refractive layer GPAL1 may not overlap with the second adjacent color filter CF2′ in a plan view. As a layer corresponding to the second refractive layer GPAL1 (e.g., including the same material) is not disposed in the second adjacent sub-pixel area GPXA, a top surface of the second adjacent color filter CF2′ may contact the overcoat layer OC. The overcoat layer OC may cover an entirety of the second adjacent color filter CF2′. The top surface of the second adjacent color filter CF2′ may be entirely adjacent directly to the overcoat layer OC.

As the second refractive layer GPAL1 is disposed on the second color filter CF2 and the layer corresponding to the second refractive layer GPAL1 (e.g., including the same material) is not disposed on the second adjacent color filter CF2′, a refractive index difference between the second color filter CF2 and the second refractive layer GPAL1 may be different from a refractive index difference between the second adjacent color filter CF2′ and a layer (e.g., the overcoat layer OC) disposed directly on the second adjacent color filter CF2′.

According to the display device DD in accordance with the first embodiment of the disclosure, as described above, the refractive layer PAL may not be disposed in at least a portion of an area in which sub-pixels SPX emitting light of the same color are formed. The refractive layer PAL may be alternately disposed in the sub-pixels SPX emitting light of the same color. In an embodiment, referring to FIG. 5, the second sub-pixel SPX2 disposed in the first area 1 may not include the second refractive layer GPAL1, the second sub-pixel SPX2 disposed in the second area 2 may include the second refractive layer GPAL1, the second sub-pixel SPX2 disposed in the third area 3 may not include the second refractive layer GPAL1, and the second sub-pixel SPX2 disposed in the fourth area 4 may include the second refractive layer GPAL1, for example.

Next, a phase control principle when the refractive layer PAL is selectively disposed on a portion of the color filter CF will be described in more detail with reference to FIGS. 9 to 11.

In FIGS. 9 to 11, a first embodiment in which the refractive layer PAL is disposed in only some sub-pixels SPX is illustrated. However, the phase control principle described in FIGS. 9 to 11 is not limited to the first embodiment, and may be applied to another embodiment.

First, referring to FIG. 9, first reflected light LGT1 reflected in a first area 1 may be transmitted through a first transmission area 10, a second transmission area 20, and a third transmission area 30. The first transmission area 10 may be an area corresponding to an area in which a second color filter CF2 may be disposed (or disposed at the same height with respect to the base layer). The second transmission area 20 may be an area corresponding to an area in which a second refractive layer GPAL1 may be disposed (or disposed at the same height with respect to the base layer). The third transmission area 30 may be an area corresponding to an area including an external area of the display area DA (or disposed at the same height with respect to the base layer).

First reflected light LGT2 reflected in a second area 2 adjacent to the first area 1 may be transmitted through a first adjacent transmission area 10′, a second adjacent transmission area 20′, and a third adjacent transmission area 30′. The first adjacent transmission area 10′, the second adjacent transmission area 20′, and the third adjacent transmission area 30′ may mean transmission areas of light, which are respectively adjacent to the first transmission area 10, the second transmission area 20, and the third transmission area 30. The first adjacent transmission area 10′, the second adjacent transmission area 20′, and the third adjacent transmission area 30′ may be areas respectively corresponding to the first transmission area 10, the second transmission area 20, and the third transmission area 30 (or disposed at the same heights with respect to the base layer).

The first adjacent transmission area 10′ may be an area corresponding to an area in which a second adjacent color filter CF2′ may be disposed (or disposed at the same height with respect to the base layer). The second adjacent transmission area 20′ is an area in which the second refractive layer GPAL1 is not disposed, and may be an area corresponding to an area corresponding to the second transmission area 20 (or disposed at the same height with respect to the base layer). The third adjacent transmission area 30′ may be an area corresponding to an area including an external area of the display device DD (or disposed at the same height with respect to the base layer).

The first reflected light LGT1 transmitted through the second refractive layer GPAL1 may be transmitted through the second refractive layer GPAL1 having a refractive index different from a refractive index of the second color filter CF2. The first reflected light LGT1 may have a phase different from a phase of second reflected light LGT2 not transmitted through the second refractive layer GPAL1. When the second reflected light LGT2 not transmitted through the second refractive layer GPAL1 is reference light NLGT, the first reflected light LGT1 having a phase different from a phase of the reference light NLGT while being transmitted through the second refractive layer GPAL1 may be provided (or defined) as changed light YLGT. That is, the reference light NLGT may have a first phase, and the changed light YLGT may have a second phase. The first phase and the second phase may be different from each other.

Referring to FIG. 10, the first reflected light LGT1 shown in FIG. 9 may have a first wave PALL in the first to third transmission areas 10 to 30. The second reflected light LGT2 shown in FIG. 9 may have a second wave NPALL in the first to third adjacent transmission areas 10′ to 30′.

The first wave PALL and the second wave NPALL may have wave shapes corresponding to each other (or having the same phase) in the first transmission area 10 and the first adjacent transmission area 10′. In an embodiment, the first wave PALL and the second wave NPALL may have the same phase in the first transmission area 10 and the first adjacent transmission area 10′, for example.

The first wave PALL and the second wave NPALL may have different wave shapes in the second transmission area 20 and the second adjacent transmission area 20′. The first wave PALL in the second transmission area 20 may have a wavelength shorter than a wavelength of the second wave NPALL in the second adjacent transmission area 20′. In an embodiment, as the first reflected light LGT1 is transmitted through the second refractive layer GPAL1, the wavelength may vary, for example. As the first reflected light LGT1 is transmitted through the second refractive layer GPAL1 having the refractive index greater than the refractive index of the second color filter CF2, the first reflected light LGT1 may have a wavelength which becomes short in the second transmission area 20.

The first wave PALL and the second wave NPALL may have wave different wave shapes in the third transmission area 30 and the third adjacent transmission area 30′. The first wave PALL in the third transmission area 30 may have the same wavelength as the second wave NPALL in the third adjacent transmission area 30′, but have different phases. While the first reflected light LGT1 is transmitted from the second refractive layer GPAL1 to the third transmission area 30, the first reflected light LGT1 may be transmitted through the overcoat layer OC having a refractive index smaller than a refractive index of the second refractive layer GPAL1, thereby having a long wavelength in the third transmission area 30. As the wavelength is changed in the second transmission area 20, a phase of the first wave PALL in the third transmission area 30 and a phase of the second wave NPALL in the third adjacent transmission area 30′ may become different from each other.

The changed light YLGT and the reference light NLGT, of which phases are different from each other, may overlap with each other, thereby forming a changed interference/diffraction pattern. The phase of the changed light YLGT may be controlled by a thickness of the refractive layer PAL and whether the refractive layer PAL exists. In the display device DD in the embodiment of the disclosure, the phase of the changed light YLGT is controlled, so that occurrence of a phenomenon in which the changed light YLGT and the reference light NLGT are constructively interfered with each other may be reduced. The phases of the changed light YLGT and the reference light NLGT, which overlap with each other, may be different from each other. Therefore, the changed light YLGT and the reference light NLGT, of which phases are different from each other, may not be constructively interfered with each other. Accordingly, the intensity of overlapping light formed by the changed light YLGT and the reference light NLGT may be decreased. As the intensity of light at a predetermined point is decreased, a risk may be reduced that a multi-image phenomenon in which one image is viewed as several images will occur.

Hereinafter, a changed pattern PHD of which constructive interference is reduced will be described with reference to FIG. 11.

The change light YLGT and the reference light NLGT may form a first changed pattern PHD1 or a second changed pattern PHD2. The change light YLGT and the reference light NLGT may form various interference patterns according to a phase difference. However, for convenience, only the first or second changed pattern PHD1 or PHD2 is illustrated. Hereinafter, the first changed pattern PHD1 or the second changed pattern PHD2 will be described.

The first changed pattern PHD1 may be an interference pattern of the change light YLGT and the reference light NLGT when the phase difference between the first wave PALL in the third transmission area 30 and the second wave NPALL in the third adjacent transmission area 30′ exceeds 0 and is less than π/2 in FIG. 10.

The second changed pattern PHD2 may be an interference pattern of the change light YLGT and the reference light NLGT when the phase difference between the first wave PALL in the third transmission area 30 and the second wave NPALL in the third adjacent transmission area 30′ π/2 or more and is π or less in FIG. 10.

A peak of the first changed pattern PHD1 and the second changed pattern PHD2 may be lower than the peak of the diffraction pattern LPH. As the peak of the first changed pattern PHD1 and the second changed pattern PHD2 is lower than the peak of the diffraction pattern LPH, an image formed by the first changed pattern PHD1 and the second changed pattern PHD2 may be viewed more weakly than an image formed by the diffraction pattern LPH. Thus, as an image of reflected light LGT reflected at the outside is viewed weakly, a risk may be reduced that a multi-image phenomenon caused by external light reflection will occur. In addition, a phenomenon in which an image is formed in an outer area of a light source may be prevented. Accordingly, the external visibility of the display device DD may be improved.

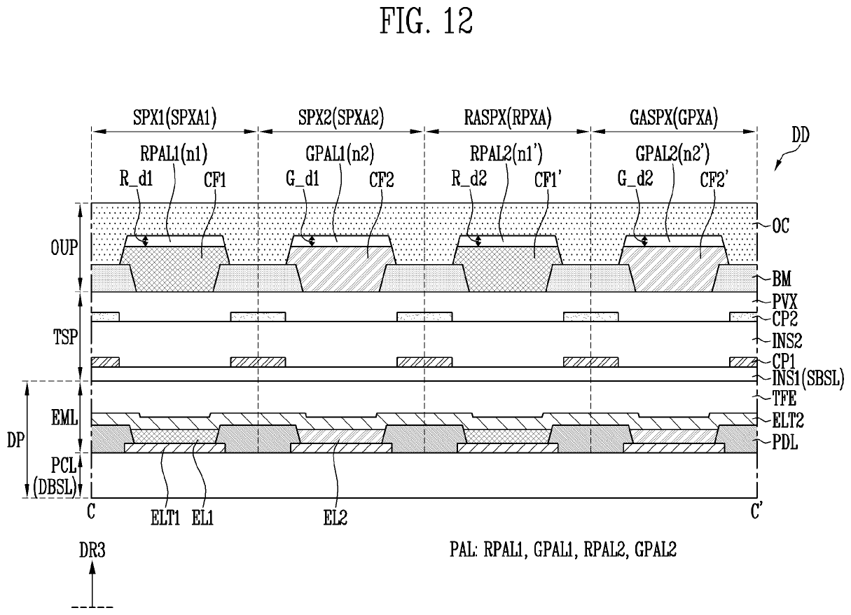

FIG. 12 is a schematic cross-sectional view of a display device in accordance with a second embodiment of the disclosure. FIG. 12 illustrates the display device of the second embodiment, which is taken along line C-C′ shown in FIG. 5. The second embodiment is different from the first embodiment, in that all sub-pixels SPX includes a refractive layer PAL, and some of sub-pixels SPX emitting light of the same color have different thicknesses or include the refractive layer PAL having different refractive indices.

The first adjacent sub-pixel RASPX adjacent to the first sub-pixel SPX1 may include a first adjacent refractive layer RPAL2. In this specification, a refractive layer disposed in the first adjacent sub-pixel area RPXA is defined as the first adjacent refractive layer RPAL2 so as to distinguish the refractive layer from the first refractive layer RPAL1 disposed in the first sub-pixel area SPXA1.

The second adjacent sub-pixel GASPX adjacent to the second sub-pixel SPX2 may include a second adjacent refractive layer GPAL2. In this specification, a refractive layer disposed in the second adjacent sub-pixel area GPXA is defined as the second adjacent refractive layer GPAL2 so as to distinguish the refractive layer from the second refractive layer GPAL1 disposed in the second sub-pixel area SPXA2.

The first adjacent refractive layer RPAL2 may be disposed on the first adjacent color filter CF1′. The first adjacent refractive layer RPAL2 may be disposed between the first adjacent color filter CF1′ and the overcoat layer OC. The first adjacent refractive layer RPAL2 may not in contact with the light-blocking members BM.

The first adjacent refractive layer RPAL2 may have a first adjacent layer refractive index n1′. The first adjacent layer refractive index n1′ may be different from the first refractive index n1.

The first adjacent refractive layer RPAL2 may have a first adjacent layer thickness R_d2. The first adjacent layer thickness R_d2 may be equal to the first thickness R_d1. The first adjacent layer thickness R_d2 may be different from the first thickness R_d1.

As the first adjacent refractive layer RPAL2 and the first refractive layer RPAL1 have different thicknesses or have different refractive indices, light transmitted through the first adjacent refractive layer RPAL2 and light transmitted through the first refractive layer RPAL1 may have different phases.

The second adjacent refractive layer GPAL2 may be disposed on the second adjacent color filter CF2′. The second adjacent refractive layer GPAL2 may be disposed between the second adjacent color filter CF2′ and the overcoat layer OC. The second adjacent refractive layer GPAL2 may not contact the light-blocking members BM.

The second adjacent refractive layer GPAL2 may have a second adjacent layer refractive index n2′. The second adjacent layer refractive index n2′ may be different from the second refractive index n2.

The second adjacent refractive layer GPAL2 may have a second adjacent layer thickness G_d2. The second adjacent layer thickness G_d2 may be equal to the second thickness G_d1. The second adjacent layer thickness G_d2 may be different from the second thickness G_d1.

As the second adjacent refractive layer GPAL2 and the second refractive layer GPAL1 have different thicknesses or have different refractive indices, light transmitted through the second adjacent refractive layer GPAL2 and light transmitted through the second refractive layer GPAL1 may have different phases.

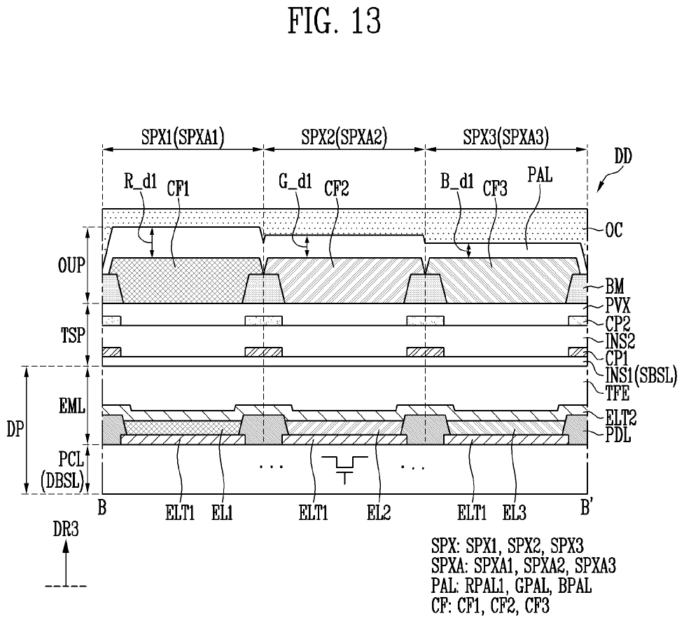

FIG. 13 is a schematic cross-sectional view of a display device in accordance with a third embodiment of the disclosure. FIG. 13 illustrates the display device of the third embodiment, which is taken along line B-B′ shown in FIG. 5. The third embodiment is different from the above-described embodiments, in that the overcoat layer OC is not provided at an uppermost portion of the outer part OUP, and a refractive layer PAL cover an entirety of the color filter CF and the light-blocking member BM.

All sub-pixels SPX of the display device DD in accordance with the third embodiment of the disclosure may include a refractive layer PAL. The refractive layer PAL may be disposed over the color filter CF and the light-blocking member BM. The refractive layer PAL may entirely cove the color filter CF and the light-blocking member BM.

The refractive layer PAL may have a first thickness R_d1 defined in an area overlapping the first light-emitting layer EL1. The refractive layer PAL may have a second thickness G_d1 defined in an area overlapping with the second light-emitting layer EL2. The refractive layer PAL may have a third thickness B_d1 defined in an area in which overlapping with the third light-emitting layer EL3.

The first thickness R_d1, the second thickness G_d1, and the third thickness B_d1 may be the same. The first thickness R_d1, the second thickness G_d1, and the third thickness B_d1 may be different from one another.

The first thickness R_d1, the second thickness G_d1, and the third thickness B_d1 may be determined by a refractive index difference between the refractive layer PAL and another component of the display device DD, which contacts the refractive layer PAL, and a wavelength of light transmitted through the refractive layer PAL.

In an embodiment, when the structure of the refractive layer PAL is designed such that the phase of reflected light LGT has a difference of π/2, the first thickness R_d1, the second thickness G_d1, and the third thickness B_d1 may be in proportion to Expression 1 under assumption that distances of reflected lights LGT overlapping with each other are the same, for example.

$$\frac{λ}{4 ( {n}_{A} - {n}_{B} )} \qquad Expression 1$$

Here, n_{A} denotes a refractive index of the refractive layer PAL, and n_{R} denotes a refractive index of another component (e.g., the color filter or the overcoat layer OC in the first embodiment and the second embodiment) adjacent to the refractive layer PAL. In addition, λ denotes a wavelength of light transmitted the refractive layer PAL.

Therefore, the first thickness R_d1, the second thickness G_d1, and the third thickness B_d1 become smaller as “n_{A}−N_{R}” becomes larger (i.e., as a refractive index difference between the refractive layer PAL and an adjacent component PAL becomes larger). The first thickness R_d1, the second thickness G_d1, and the third thickness B_d1 become smaller as A becomes smaller.

Experimentally, among reflected lights LGT, a wavelength of light transmitted through the first color filter CF1 capable of allowing light of red to be transmitted therethrough and then transmitted the refractive layer PAL may be longer than a wavelength of light transmitted through the third color filter CF3 capable of allowing light of blue to be transmitted therethrough and then transmitted through the refractive layer PAL. Therefore, in some embodiments, the first thickness R_d1 may be greater than the second thickness G_d1, and the second thickness G_d1 may be greater than the third thickness B_d1.

When the first thickness R_d1, the second thickness G_d1, and the third thickness B_d1 are different from one another, the refractive layer PAL may be light-exposed for different times for each area in a manufacturing process of the display device DD. The refractive layer PAL may include an area light-exposed for different times. The light-exposed area of the refractive layer PAL may include an area overlapping with an area in which the first color filter CF1 is disposed, an area overlapping with an area in which the second color filter CF2 is disposed, and an area overlapping with an area in which the third color filter CF3 is disposed. The area overlapping with the area in which the first color filter CF1 is disposed, the area overlapping with the area in which the second color filter CF2 is disposed, and the area overlapping with the area in which the third color filter CF3 is disposed may be light-exposed according to different times. In an embodiment, in order to etch the refractive layer PAL overlapping with the first light-emitting layer EL1, a time for which the refractive layer PAL overlapping with the first light-emitting layer EL1 is light-exposed and a time for which the refractive layer PAL overlapping with the second light-emitting layer EL2 is light-exposed may be different from each other, for example.

In accordance with the disclosure, there may be provided a display device capable of enhancing the display quality of the display device by improving the external visibility of the display device.

Embodiments have been disclosed herein, and although predetermined terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in any combinations with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a base layer; and
sub-pixels disposed on the base layer, the sub-pixels including:
first sub-pixels including:
a first sub-pixel including:
a first color filter; and
a first refractive layer disposed on the first color filter; and
a first adjacent sub-pixel including:
a first adjacent color filter disposed in a same layer as the first color filter; and
second sub-pixels including:
a second sub-pixel disposed between the first sub-pixel and the first adjacent sub-pixel,
wherein a refractive index difference between the first color filter and the first refractive layer is different from a refractive index difference between the first adjacent color filter and a layer disposed directly on the first adjacent color filter.

2. The display device of claim 1, wherein the second sub-pixels include the second sub-pixel disposed in each of a first area, a second area, and a third area, which are sequentially disposed adjacent to each other,
wherein the second sub-pixel disposed in the second area includes a second color filter and a second refractive layer disposed on the second color filter, and
wherein the second sub-pixel disposed in the first area and the second sub-pixel disposed in the third area do not include the second refractive layer.

3. The display device of claim 2, wherein the first refractive layer does not overlap with the first adjacent color filter in a plan view, and
wherein the first refractive layer contacts a top surface of the first color filter.

4. The display device of claim 3, further comprising an overcoat layer entirely covering each of the first color filter and the first adjacent color filter,
wherein the overcoat layer is not in contact with the top surface of the first color filter but in contact with a top surface of the first adjacent color filter,
wherein the first refractive layer has a first refractive index greater than a refractive index of the overcoat layer and a refractive index of the first color filter, and
wherein the first refractive index is 1.5 or more.

5. The display device of claim 4, wherein the first refractive layer includes an inorganic material or an organic material, which has a refractive index of 1.5 or more,
wherein the inorganic material includes at least one of copper (Cu), iodine (I), thallium (Tl), silver (Ag), cadmium (Cd), mercury (Hg), tin (Sn), lead (Pb), zinc (Zn), and iron (Fe), or a metal oxide such as titanium oxide (TiOₓ), tantalum oxide (TaOₓ), hafnium oxide (HfOₓ), and zirconium oxide (ZrOₓ), and
wherein the organic material includes at least one of PEDOT, TPD, m-MTDATA, o-MTDAB, m-MTDAB, p-MTDAB, BPPM, TPBI, and TAZ.

6. The display device of claim 4, wherein external light applied to the display device has a first phase when the external light is transmitted through the first refractive layer,
wherein the external light applied to the display device has a second phase when the external light is not transmitted through the first refractive layer, and
wherein the first phase and the second phase are different from each other.

7. The display device of claim 1, wherein the sub-pixels further include third sub-pixels,
wherein the second sub-pixels further include a second adjacent sub-pixel adjacent to the second sub-pixel with the first sub-pixel interposed therebetween,
wherein the second sub-pixel includes a second color filter disposed in the same layer as the first color filter and a second refractive layer disposed on the second color filter,
wherein the second adjacent sub-pixel includes a second adjacent color filter disposed in a same layer as the second color filter, and
wherein the third sub-pixel includes a third color filter disposed in the same layer as the first color filter and a third refractive layer disposed on the third color filter.

8. The display device of claim 7, wherein the first refractive layer has a first thickness,
the second refractive layer has a second thickness, and
the third refractive layer has a third thickness, and
wherein the first thickness, the second thickness, and the third thickness are different from one another.

9. The display device of claim 7, wherein the first refractive layer, the second refractive layer, and the third refractive layer have a first refractive index, a second refractive index, and third refractive index, which are different refractive indices of 1.5 or more, as refractive indices greater than refractive indices of the first color filter, the second color filter, and the third color filter.

10. The display device of claim 7, wherein the first refractive layer, the second refractive layer, and the third refractive layer have a first refractive index, a second refractive index, and third refractive index, which are a same refractive index of about 1.5 or more, as refractive indices greater than refractive indices of the first color filter, the second color filter, and the third color filter.

11. A display device comprising:
a base layer; and
sub-pixels disposed on the base layer, the sub-pixels including:
first sub-pixels including:
a first sub-pixel including:
a first color filter; and
a first refractive layer disposed on the first color filter; and
a first adjacent sub-pixel including a first adjacent color filter disposed in a same layer as the first color filter and a first adjacent refractive layer disposed on the first adjacent color filter; and
second sub-pixels including:
a second sub-pixel disposed between the first sub-pixel and the first adjacent sub-pixel,
wherein a phase of light transmitted through the first refractive layer and a phase of light transmitted through the first adjacent refractive layer are different from each other.

12. The display device of claim 11, further comprising light-blocking members disposed between the first adjacent color filter and the first color filter,
wherein the first refractive layer contacts the first color filter, and is not in contact with the light-blocking members, and
wherein the first adjacent refractive layer contacts the first adjacent color filter, and is not in contact with the light-blocking members.

13. The display device of claim 12, further comprising an overcoat layer entirely covering the first adjacent color filter and the first color filter,
wherein the first refractive layer has a first refractive index greater than a refractive index of the first color filter and the overcoat layer,
wherein the first adjacent refractive layer has a first adjacent layer refractive index greater than a refractive index of the first adjacent color filter and the overcoat layer, and
wherein each of the first refractive index and the first adjacent layer refractive index is 1.5 or more.

14. The display device of claim 13, wherein the first refractive index and the first adjacent layer refractive index are different from each other.

15. The display device of claim 13, wherein the first refractive layer has a first thickness, and
wherein the first adjacent refractive layer has a first adjacent layer thickness different from the first thickness.

16. The display device of claim 11, wherein the sub-pixels further include third sub-pixels,
wherein the second sub-pixel includes a second color filter disposed in the same layer as the first color filter and a second refractive layer which is disposed on the second color filter and contacts the second color filter, and
wherein at least one of the third sub-pixels includes a third color filter disposed in the same layer as the first color filter and a third refractive layer which is disposed on the third color filter and contacts the third color filter.

17. The display device of claim 16, wherein the first refractive layer has a first thickness,
the second refractive layer has a second thickness, and
the third refractive layer has a third thickness, and
wherein the first thickness, the second thickness, and the third thickness are different from one another.

18. A display device comprising:
a display unit including a light-emitting element; and
an outer part on the display unit, the outer part including:
color filters disposed above the light-emitting element;
light-blocking members disposed between the color filters; and
a refractive layer disposed over the color filters and the light-blocking members and covering an entirety of a top surface of each of the color filters and the light-blocking members, and
wherein the refractive layer has a refractive index of 1.5 or more as a refractive index greater than a refractive index of the color filters.

19. The display device of claim 18, wherein the color filters include a first color filter through which light of a first color is transmitted, a second color filter through which light of a second color is transmitted, and a third color filter through which light of a third color is transmitted,
wherein the refractive layer has a first thickness defined in an area overlapping with the first color filter, a second thickness defined in an area overlapping with the second color filter, and a third thickness defined in an area overlapping with the third color filter, and
wherein the first thickness, the second thickness, and the third thickness are different from one another.

20. The display device of claim 19, wherein the refractive layer includes an area light-exposed according to different times,
wherein the area light-exposed according to the different times includes an area overlapping with the first color filter, an area overlapping with the second color filter, and an area overlapping with the third color filter, and
wherein, as the area light-exposed according to the different times is exposed according to different times, the first thickness, the second thickness, and the third thickness are different from one another.
